(19) United States
(12) Patent Application Publication
(10) Pub. No.: US 2026/0190815 A1
(43) Pub. Date: Jul. 2, 2026

(54) DISPLAY APPARATUS WITH OPTICAL IMPROVEMENT LAYER

(71) Applicant: LG Display Co., Ltd., Seoul (KR)

(72) Inventors: SeungSoo YANG, Paju-si (KR); JuHun MIN, Paju-si (KR); SunWoong KIM, Paju-si (KR); DongUk KIM, Paju-si (KR)

(73) Assignee: LG Display Co., Ltd., Seoul (KR)

(21) Appl. No.: 19/434,724

(22) Filed: Dec. 29, 2025

(30) Foreign Application Priority Data
Dec. 30, 2024 (KR) 10-2024-0200134

(51) Int. Cl. H10K 59/80

(52) U.S. Cl. CPC H10K 59/879

(57) ABSTRACT

Discussed is a display apparatus including a display panel having pixels, and an optical improvement layer on the display panel. The optical improvement layer includes a first pattern layer and a second pattern layer overlapping each other. The first pattern layer has a first refractive index, the second pattern layer has a second refractive index different from that of the first refractive index, the first pattern layer has an average pattern size greater than that of the second pattern layer, and an average of pattern ratios of patterns included in the first pattern layer is smaller than an average of pattern ratios of patterns included in the second pattern layer.

### CROSS-REFERENCE TO RELATED APPLICATION

This application claims priority to Korean Patent Application No. 10-2024-0200134, filed in the Republic of Korea on Dec. 30, 2024, which is hereby expressly incorporated by reference in its entirety.

### BACKGROUND

### Field of Technology

The present disclosure relates to a display apparatus including an optical improvement layer and thus capable of preventing or suppressing a sandy phenomenon caused by external light and a sparkling phenomenon caused by an internal light source.

### Discussion of the Related Art

The organic light emitting diode (OLED) displays are attracting attention as next-generation flat panel displays because OLED displays can feature fast response times, low power consumption, and excellent viewing angles as self-luminous devices that do not require a separate light source. Furthermore, OLED displays offer the advantage of being easily adaptable to flexible displays.

The display apparatus that can include the OLED displays can include a display panel on which images are displayed. Furthermore, a light-transmitting cover substrate is typically disposed on the display surface of the display panel. Also, the cover substrate can be surface-treated to prevent glare.

In order to prevent glare which is perceived from the cover substrate, irregular micro-patterns can be formed on the cover substrate. When such irregular patterns are arranged, due to irregularity or non-uniformity caused by the irregularly arranged multiple patterns, a sparkling phenomenon can occur when the light emitting element emits light. The sparkling phenomenon refers to a phenomenon in which bright areas and dark areas on the display surface appear irregularly and appear as spots, corresponding to the intervals between the patterns.

Meanwhile, when light is incident from outside the display apparatus (external light incident), reflection and refraction occur in each layer that constitutes the cover substrate and display panel, and due to the fluctuation deviation of the reflected or refracted light, a blurry area, that looks similar to sand being sprinkled on it, can occur near the point where the reflected external light is recognized. This phenomenon is called the sandy phenomenon.

If sparkling phenomenon or the sandy phenomenon occurs, the display quality of the display apparatus can deteriorate. Therefore, it is necessary or desirable to prevent or suppress the sparkling phenomenon or the sandy phenomenon in the display apparatus.

### SUMMARY OF THE DISCLOSURE

One embodiment of the present disclosure is to provide a display apparatus that can effectively overcome the occurrence of a sparkling phenomenon or a sandy phenomenon.

One embodiment of the present disclosure is to provide a display apparatus that can effectively suppress a sparkling phenomenon that occurs when an internal light emitting element emits light (in an ON state) and a sandy phenomenon that occurs when external light is reflected on a display surface.

One embodiment of the present disclosure provides a technology capable of effectively overcoming a sparkling phenomenon or a sandy phenomenon in a display apparatus by disposing an optical improvement layer having a first pattern layer and a second pattern layer having different pattern shapes each other on a display panel.

One embodiment of the present disclosure provides a display apparatus capable of preventing a sparkling phenomenon or a sandy phenomenon by having an optical improvement layer capable of effectively suppressing the sparkling phenomenon or the sandy phenomenon.

One embodiment of the present disclosure is to provide an optical sheet that can effectively suppress a sparkling phenomenon or a sandy phenomenon occurring in a display apparatus.

One embodiment of the present disclosure for achieving the above described technical problem provides a display apparatus including a display panel having pixels and an optical improvement layer on the display panel, wherein the optical improvement layer includes a first pattern layer and a second pattern layer overlapping each other, the first pattern layer has a first refractive index, the second pattern layer has a second refractive index different from the first refractive index, the first pattern layer has an average pattern size greater than the second pattern layer, and an average of pattern ratio of patterns included in the first pattern layer is smaller than an average of pattern ratio of patterns included in the second pattern layer.

The average pattern size is an average value of maximum diameters of respective patterns in a plan-view image for each of the first pattern layer and the second pattern layer, wherein the pattern ratio is calculated as “b/a,” where “a” denotes a maximum diameter of each pattern, and “b” denotes a height of the pattern, and the average of the pattern ratio is calculated as an average value of the pattern ratio of the plurality of patterns.

The first pattern layer can have a plurality of lens patterns.

The second pattern layer can include a plurality of patterns having a horn-shaped shape.

The optical improvement layer can further include an intermediate layer on the first pattern layer.

The intermediate layer can contact the first pattern layer, and the first pattern layer and the intermediate layer can have a refractive index difference of 0.05 to 0.1.

The intermediate layer can contact the first pattern layer and the second pattern layer, and the difference in refractive index between the intermediate layer and the second pattern layer can be 0.01 or less.

The intermediate layer can be made of the same material as the second pattern layer.

The intermediate layer can be formed integrally with the second pattern layer.

The first pattern layer and the second pattern layer can have a refractive index difference of 0.05 to 0.1.

The optical improvement layer can further include a filling layer on the second pattern layer.

The filling layer contacts the second pattern layer, and the second pattern layer and the filling layer can have a refractive index difference of 0.05 to 0.1.

The intermediate layer and the filling layer can be disposed between the first pattern layer and the second pattern layer.

The intermediate layer and the above filling layer can be made of the same material.

The optical improvement layer can further include a spacer disposed between the intermediate layer and the filling layer.

The filling layer can be disposed between the first pattern layer and the second pattern layer.

The filling layer can be formed integrally with the first pattern layer.

The first pattern layer can contact the second pattern layer, and the protrusions of the first pattern layer and the protrusions of the second pattern layer can protrude in opposite directions.

The first pattern layer and the second pattern layer can be formed integrally.

The difference in refractive index between the first pattern layer and the intermediate layer can be the same as the difference in refractive index between the second pattern layer and the filling layer.

The display apparatus further includes a cover substrate on the filling layer, and the filling layer can have the same refractive index as the cover substrate.

The display panel includes an overcoat layer, the first pattern layer is disposed on the overcoat layer, and the overcoat layer can have the same refractive index as the first pattern layer.

The display panel includes a color filter layer, and the optical improvement layer can be disposed on the color filter layer.

Another embodiment of the present disclosure provides an optical improvement layer comprising a first pattern layer and a second pattern layer overlapping each other, wherein the first pattern layer has a first refractive index, the second pattern layer has a second refractive index different from the first refractive index, the first pattern layer has the average pattern size greater than the second pattern layer, and an average of a pattern ratio of patterns included in the first pattern layer is smaller than an average of a pattern ratio of patterns included in the second pattern layer.

### BRIEF DESCRIPTION OF THE DRAWINGS

The other objects, features and other advantages of the present disclosure will be more clearly understood from the following detailed description taken in conjunction with the accompanying drawings, in which:

FIG. 1 is a schematic diagram of a display apparatus according to one embodiment of the present disclosure.

FIG. 2 is a schematic diagram of one embodiment of a display panel.

FIG. 3 is a plan view of a structure of a pixel illustrated in FIG. 2.

FIG. 4 is a cross-sectional view of a structure of one subpixel of FIG. 3.

FIG. 5 is a partial cross-sectional view of an optical improvement layer of FIG. 4.

FIG. 6A is a plan view of a first pattern layer, and FIG. 6B is a plan view of a second pattern layer.

FIG. 7A and FIG. 7B are schematic diagrams explaining the mechanism by which the sparkling phenomenon is eliminated.

FIG. 8A and FIG. 8B are schematic diagrams explaining the mechanism by which the sandy phenomenon is eliminated.

FIG. 9 is a partial cross-sectional view of a display apparatus according to another embodiment of the present disclosure.

FIG. 10 to FIG. 16 are partial cross-sectional views of the optical improvement layers applied to a display apparatus according to another embodiment of the present disclosure, respectively.

FIG. 17A is a partial cross-sectional view of a display apparatus according to Comparative Example 1, and FIG. 17B is a partial cross-sectional view of a display apparatus according to Comparative Example 2.

FIG. 18 is an image showing the elimination of a sparkling phenomenon and a sandy phenomenon.

FIG. 19A to FIG. 19H are schematic cross-sectional views illustrating a method for manufacturing an optical improvement layer according to one embodiment of the present disclosure.

FIG. 20A to FIG. 20C are schematic perspective views illustrating a method for manufacturing a first roller for forming a first pattern layer.

FIG. 21A to FIG. 21C are schematic perspective views illustrating a method for manufacturing a second roller for forming a second pattern layer.

### DETAILED DESCRIPTION OF THE EMBODIMENTS

The advantages and features of the present disclosure, and the methods for achieving them, will become clearer with reference to the embodiments described in detail below, along with the accompanying drawings. However, the present disclosure is not limited to the embodiments disclosed below, but can be implemented in various different forms. These embodiments are provided solely to ensure that the disclosure of the present disclosure is complete and to inform those skilled in the art of the scope of the invention.

The shapes, sizes, ratios, angles, numbers, etc. disclosed in the drawings for explaining embodiments of the present disclosure are merely illustrative, and the present disclosure is not limited to the details depicted in the drawings. Throughout the disclosure, identical components can be designated by identical reference numerals. Furthermore, in describing the present disclosure, if a detailed description of a related known technology is deemed to unnecessarily obscure the gist of the present disclosure, the detailed description will be omitted.

In this disclosure, when the words “include,” “have,” and “consist of” are used, other parts can be added, unless the expression “only” is used. When a component is expressed in the singular, the plural is included unless otherwise explicitly stated.

When interpreting a component, it is interpreted as including the error range even if there is no separate explicit description.

For example, when the positional relationship between two parts is described as “on ˜”, “above ˜”, “below ˜”, “next to ˜”, etc., one or more other parts can be located between the two parts, unless the expression “right” or “directly” is used.

Spatially relative terms such as “below,” “beneath,” “lower,” “above,” and “upper” can be used to easily describe the relationship between one element or component and other elements or components as depicted in the drawings. Spatially relative terms should be understood to include different orientations of the elements during use or operation in addition to the orientations depicted in the drawings. For example, if an element depicted in the drawings is flipped over, an element described as “below” or “beneath” another element can end up “above” the other element. Thus, the example term “below” can include both directions of below and above. Similarly, the example term “above” can include both directions of above and below.

When describing a temporal relationship, for example, when the temporal continuity is described as “after ˜,” “following ˜,” “next to ˜,” or “before ˜,” it can also include cases where it is not continuous, as long as the expression “immediately” or “directly” is not used.

While terms like “first” and “second” are used to describe various components, these components are not limited by these terms. These terms are used merely to distinguish one component from another. Therefore, a “first” component referred to below can also be a “second” component within the technical scope of the present disclosure.

The term “at least one” should be understood to include all possible combinations of one or more associated items. For example, “at least one of the first, second, and third items” can mean not only the first, second, or third items, but also any combination of items that can be represented by two or more of the first, second, and third items.

The features of each of the various embodiments of the present disclosure can be partially or wholly combined or combined with each other, and various technical connections and operations are possible, and each embodiment can be implemented independently of each other or implemented together in a related relationship.

In adding reference numerals to components of each drawing describing embodiments of the present disclosure, the same components can have the same numerals as much as possible even if they are shown in different drawings.

Hereinafter, examples of the present disclosure will be described with reference to the attached drawings and examples. The scales of the components illustrated in the drawings are different from the actual scale for convenience of explanation, and are therefore not limited to the scales illustrated in the drawings.

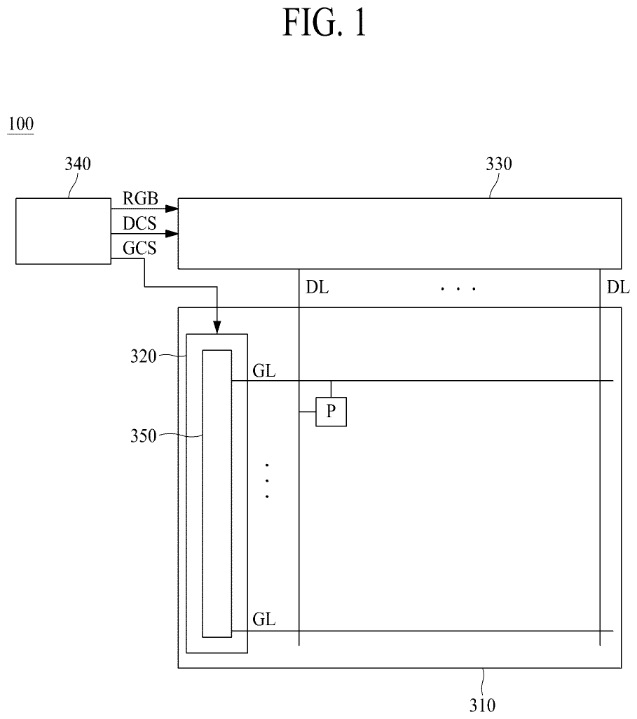

FIG. 1 is a schematic diagram of a display apparatus 100 according to one embodiment of the present disclosure. All components of each display apparatus according to all embodiments of the present disclosure are operatively coupled and configured.

A display apparatus 100 according to another embodiment of the present disclosure can include a display panel 310, a gate driver 320, a data driver 330, and a control unit 340, as illustrated in FIG. 1.

The gate lines GL and data lines DL are disposed on the display panel 310, and pixels P are arranged at the intersections of the gate lines GL and the data lines DL. An image is displayed by driving the pixels P.

The control unit 340 controls the gate driver 320 and the data driver 330.

The control unit 340 outputs a gate control signal GCS for controlling the gate driver 320 and a data control signal DCS for controlling the data driver 330 using a signal supplied from an external system. In addition, the control unit 340 samples input image data input from the external system, rearranges it, and supplies the rearranged digital image data RGB to the data driver 330.

The gate control signal GCS includes a gate start pulse (GSP), a gate shift clock (GSC), a gate output enable signal (GOE), a start signal (Vst), and a gate clock (GCLK). In addition, the gate control signal GCS can include control signals for controlling a shift register 350.

The data control signal DCS includes a source start pulse (SSP), a source shift clock signal (SSC), a source output enable signal (SOE), and a polarity control signal (POL).

The data driver 330 supplies data voltage to the data lines DL of the display panel 310. Specifically, the data driver 330 converts image data (RGB) input from the control unit 340 into analog data voltage and supplies the data voltage to the data lines DL.

The gate driver 320 can include a shift register 350.

The shift register 350 sequentially supplies gate pulses to the gate lines GL for one frame using a start signal and a gate clock transmitted from the control unit 340. Here, one frame refers to a period during which one image is output through the display panel 310. The gate pulse has a turn-on voltage capable of turning on a switching element (thin film transistor) disposed in a pixel P.

Additionally, the shift register 350 supplies a gate-off signal capable of turning off the switching element to the gate line GL during the remaining period during which the gate pulse is not supplied during one frame. Hereinafter, the gate pulse and the gate-off signal are collectively referred to as a scan signal (SS or Scan).

According to one embodiment of the present disclosure, the gate driver 320 can be mounted on the display panel 310. In this way, a structure in which the gate driver 320 is directly mounted on the display panel 310 is called a Gate In Panel GIP structure.

The gate driver 320 can include a plurality of thin film transistors. The plurality of thin film transistors can be disposed in a shift register 350.

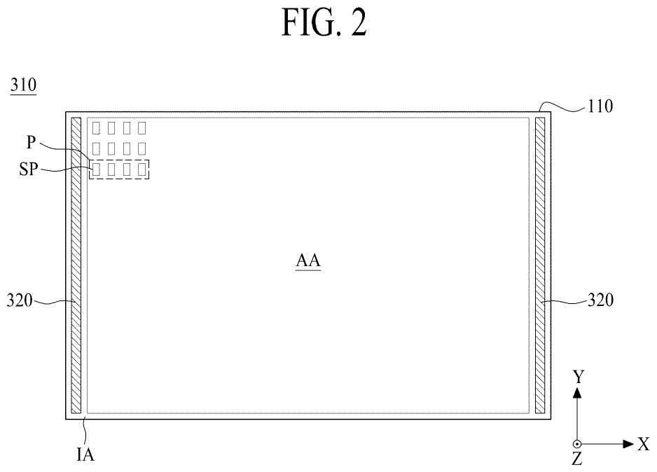

FIG. 2 is a schematic diagram of one embodiment of a display panel 310. FIG. 2 illustrates an organic light emitting panel as an example of a display panel 310 applied to a display apparatus 100. The display apparatus 100 of FIG. 1, including an organic light emitting panel, can be referred to as an organic light emitting display apparatus.

Referring to FIG. 2, the display panel 310 includes a substrate 110 and pixels P on the substrate 110.

The glass substrate or a plastic substrate can be used as the substrate 110. The substrate 110 can include a display area AA and a non-display area IA.

The display area AA is the area where an image is displayed, and can be referred to as a pixel array area, an active area, a pixel array unit, a display unit, or a screen. The display area AA includes a plurality of pixels P.

A plurality of pixels P can be disposed along a first direction X and a second direction Y crossing the first direction X. For example, the first direction X can be referred to as a first longitudinal direction, a long-side longitudinal direction, a horizontal direction, or a first horizontal direction of the substrate 110. In addition, the second direction Y can be referred to as a second longitudinal direction, a short-side longitudinal direction, a vertical direction, a second horizontal direction, or a vertical direction of the substrate 110.

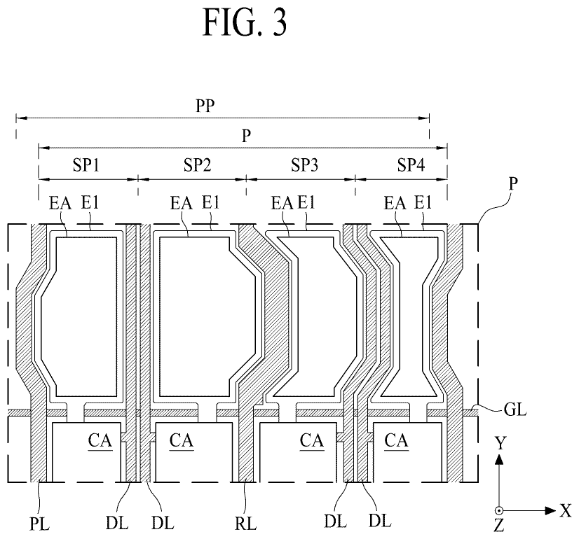

Each of the plurality of pixels P can be a unit area where actual light is emitted. For example, the plurality of pixels P can be disposed to have a pixel pitch (PP; see FIG. 3) along the first direction X. For example, the pixel pitch PP can be defined as the size of each of the plurality of pixels P with respect to the first direction X, the distance between one side of each of two adjacent pixels P along the first direction X, or the distance between the centers of two adjacent pixels P along the first direction X.

Each of the plurality of pixels P can include a plurality of adjacent sub pixels SP. For example, a plurality of sub pixels SP can constitute one pixel P.

The non-display area IA is an area where an image is not displayed. The non-display area IA can include at least one of a peripheral circuit area, a signal supply area, an inactive area, and a bezel area. The non-display area IA can also be referred to as, for example, a peripheral circuit area, a signal supply area, an inactive area, or a bezel area.

The non-display area IA can be configured to surround the display area AA. The display panel 310 can include a gate driver 320 disposed on the non-display area IA of the substrate 110. The gate driver 320 can also be referred to as a peripheral circuit. The gate driver 320 can be disposed on both sides of the substrate 110.

FIG. 3 is a plan view of the structure of the pixel P illustrated in FIG. 2. In FIG. 2 and FIG. 3, the X-axis is the horizontal direction of the drawing, the Y-axis is the vertical direction of the drawing, and the Z-axis is the thickness direction.

Referring to FIG. 2 and FIG. 3, in the display panel 310 of the display apparatus 100 according to one embodiment of the present disclosure, each of the plurality of pixels P can include, for example, four sub pixels SP1, SP2, SP3, SP4, but embodiments of the present disclosure are not limited thereto, and different number of sub pixels may be used.

In one embodiment of the present disclosure, a pixel P can include first, second, third, and fourth sub pixels SP1, SP2, SP3, SP4 adjacent to each other along a first direction X. For example, each of the plurality of pixels P can include a first red sub pixel SP1, a second white sub pixel SP2, a third green sub pixel SP3, and a fourth blue sub pixel SP4, but embodiments of the present disclosure are not limited thereto. According to one embodiment of the present disclosure, each of the first to fourth sub pixels SP1 to SP4 can be configured to have different sizes or areas.

Each of the first, second, third and fourth sub pixels SP1, SP2, SP3, SP4 can include an emission area EA and a circuit area CA.

The emission area EA can be disposed on one side of the sub pixel area, for example, on the upper side. The emission area EA of each of the first, second, third, and fourth sub pixels SP1, SP2, SP3, SP4 can have different sizes or areas. According to one embodiment of the present disclosure, the emission area EA can also be referred to as an aperture area or a light emitting area.

According to one embodiment of the present disclosure, among the emission areas EA of each of the first, second, third, and fourth sub pixels SP1, SP2, SP3, and SP4, the emission area EA of the second sub pixel SP2 can have the largest size, and the emission area EA of the fourth sub pixel SP4 can have the smallest size. The emission area EA of the first sub pixel SP1 can be smaller than the emission area EA of the second sub pixel SP2, and can have a larger size than the emission areas EA of each of the third and fourth sub pixels SP3, SP4. In addition, the emission area EA of the third sub pixel SP3 can have a larger size than the emission area EA of the fourth sub pixel SP4. However, one embodiment of the present disclosure is not limited thereto.

According to one embodiment of the present disclosure, in each of the first, second, third, and fourth sub pixels SP1, SP2, SP3, SP4, the circuit area CA can be spatially separated from the emission area EA. For example, the circuit area CA can be disposed on the other side or lower side of the sub pixel area. For example, the circuit area CA can be a non-light emitting area or a non-aperture area. However, one embodiment of the present disclosure is not limited thereto.

At least a portion of the circuit area CA can overlap with the emission area EA. For example, in each of the sub pixels SP1, SP2, SP3, SP4, the circuit area CA can overlap the entire emission area EA or be disposed below the emission area EA. According to one embodiment of the present disclosure, the emission area EA can extend above the circuit area CA, and the entire circuit area CA can overlap with the emission area EA.

Each of the plurality of pixels P can further include a light-transmitting area disposed around at least one of the emission area EA and the circuit area CA of each of the first, second, third, and fourth sub pixels SP1, SP2, SP3, and SP4. For example, each of the plurality of pixels P can include a pixel-specific emission area EA corresponding to each of the plurality of sub pixels SP1 to SP4, and a light transmitting area disposed around each of the plurality of sub pixels SP1 to SP4. In this case, the display apparatus 100 can implement a transparent display apparatus due to light transmission of the light transmitting area. A transparent display apparatus including an organic light emitting panel can be referred to as a transparent organic light emitting display apparatus.

Referring to FIG. 3, two data lines DL extending along the second direction Y can be disposed parallel to each other between the first sub pixel SP1 and the second sub pixel SP2, and between the third sub pixel SP3 and the fourth sub pixel SP4. A gate line GL extending along the first direction X can be disposed between the emission area EA and the circuit area CA of each of the first to fourth sub pixels SP1 to SP4. A pixel power line PL extending along the second direction Y can be disposed on one side of the first sub pixel SP1 or the fourth sub pixel SP4. A reference line RL extending along the second direction Y can be disposed between the second sub pixel SP2 and the third sub pixel SP3. The reference line RL can be used as a sensing line for externally sensing a change in the characteristics of a driving thin film transistor disposed in a circuit area CA and/or a change in the characteristics of a light emitting element layer when the pixel P is in sensing driving mode.

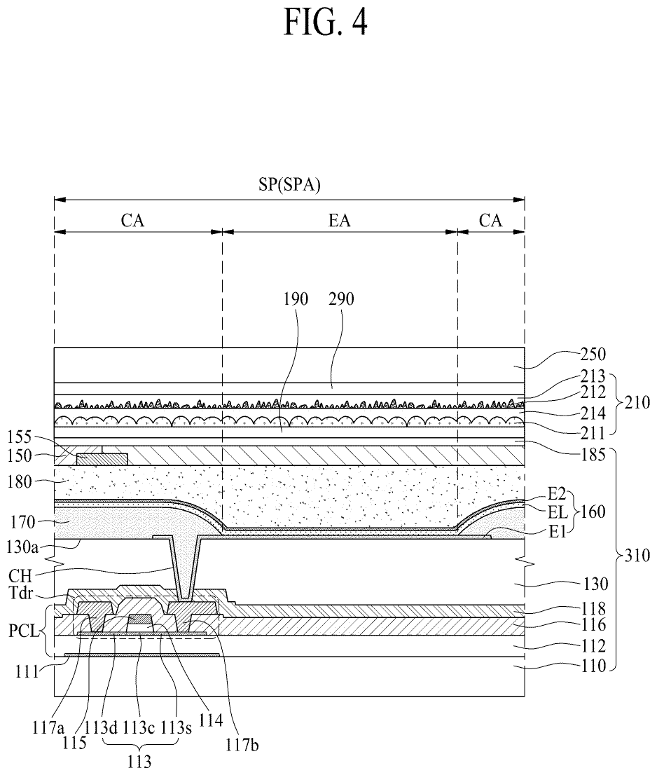

FIG. 4 is a cross-sectional view of the structure of one sub pixel SP of FIG. 3.

Referring to FIG. 3 and FIG. 4, A display apparatus 100 according to one embodiment of the present disclosure includes a display panel 310 including pixels P and an optical improvement layer 210 on the display panel 310. The display panel 310 can include a substrate 110, a pixel circuit layer PCL, an organic light emitting element 160, and an encapsulation layer 180.

The substrate 110 can also be referred to as a first substrate, a base substrate, a lower substrate, a glass substrate, a plastic substrate, or a base member. According to one embodiment of the present disclosure, glass or plastic can be used as the substrate 110. A transparent plastic having flexible property, such as polyimide, can be used as the plastic. When polyimide is used as the substrate 110, considering that a high-temperature deposition process is performed on the substrate 110, a heat-resistant polyimide that can withstand high temperatures can be used.

A pixel circuit layer PCL can be disposed on a substrate 110. The pixel circuit layer PCL can include a buffer layer 112, a pixel circuit, and a protective layer 118.

The buffer layer 112 can be disposed on the first surface or the entire upper surface of the substrate 110. The buffer layer 112 can serve to block a material contained in the substrate 110 from diffusing into the transistor layer during a high-temperature process during the manufacturing process of the thin film transistor, or can serve to prevent external moisture or humidity from penetrating toward the organic light emitting element 160. Optionally, the buffer layer 112 can be omitted.

The pixel circuit can include a driving thin film transistor Tdr disposed in a circuit area CA of each subpixel SP. The driving thin film transistor Tdr can include an active layer 113, a gate insulating layer 114, a gate electrode 115, an interlayer insulating layer 116, a drain electrode 117a, and a source electrode 117b.

The active layer 113 can comprise a semiconductor material based on any one of amorphous silicon, polycrystalline silicon, oxide, and organic material. The active layer 113 can include a channel part 113c, a drain region 113d, and a source region 113s.

The gate insulating layer 114 can be disposed on the active layer 113. The gate insulating layer 114 can be disposed in an island shape only on the channel part 113c of the active layer 113, or can be disposed on the entire upper surface of the substrate 110 or buffer layer 112 including the active layer 113.

The gate electrode 115 can be disposed on the gate insulating layer 114 so as to overlap with the channel part 113c of the active layer 113.

An interlayer insulating layer 116 can be formed on the gate electrode 115 and the drain region 113d and source region 113s of the active layer 113. The interlayer insulating layer 116 can be formed on the entire upper surface of the substrate 110 or the buffer layer 112. For example, the interlayer insulating layer 116 can be made of an inorganic material or an organic material.

The drain electrode 117a can be disposed on the interlayer insulating layer 116 so as to be electrically connected to the drain region 113d of the active layer 113. The source electrode 117b can be disposed on the interlayer insulating layer 116 so as to be electrically connected to the source region 113s of the active layer 113.

The pixel circuit can further include at least one capacitor disposed in a circuit area CA together with a driving thin film transistor Tdr, and at least one switching thin film transistor.

The display apparatus 100 according to one embodiment of the present disclosure can further include a light shielding layer 111. The light shielding layer 111 can be disposed on the substrate 110 to overlap with the active layer 113, and configured to minimize or prevent a change in the threshold voltage of the thin film transistor due to external light. According to the present disclosure, the light shielding layer 111 can be disposed under the active layer 113 of the driving thin film transistor Tdr or the switching thin film transistor.

A protective layer 118 can be disposed over the pixel circuit. For example, the protective layer 118 can be configured to surround the drain electrode 117a and the source electrode 117b of the driving thin film transistor Tdr and the interlayer insulating layer 116. For example, the protective layer 118 can be formed of an inorganic insulating material. The protective layer 118 can also be referred to as a passivation layer or an interlayer insulating layer.

The planarization layer 130 can be disposed on the pixel circuit layer PCL. The planarization layer 130 can be formed in the entire display area AA and the remaining area of the non-display area IA excluding the pad area. For example, the planarization layer 130 can include an extension portion extending from the display area AA toward the remaining non-display area IA excluding the pad area. Accordingly, the planarization layer 130 can have a size that is relatively larger than the display area AA.

According to one embodiment of the present disclosure, the planarization layer 130 can be formed to have a relatively thick thickness to provide a planar surface 130a on the pixel circuit layer PCL. For example, the planarization layer 130 can be made of an organic material.

An organic light emitting element 160 can be disposed in an emission area EA of each sub pixel SP. According to one embodiment of the present disclosure, the organic light emitting element 160 can include a first electrode E1, an emission layer EL, and a second electrode E2.

According to one embodiment of the present disclosure, the first electrode E1, the light emitting layer EL, and the second electrode E2 can be configured to emit light toward the opposite side of the substrate 110 according to a top emission method, or can be configured to emit light toward the substrate 110 according to a bottom emission method.

Hereinafter, embodiments of the present disclosure will be described, focusing on a display apparatus 100 including an organic light emitting element 160 configured to emit light toward the opposite side of a substrate 110 according to a top emission method.

The first electrode E1 can be formed on a planarization layer 130 of a sub pixel area SPA and can be electrically connected to a source electrode 117b of a driving thin film transistor Tdr. One end of the first electrode E1 adjacent to the circuit area CA can be electrically connected to a source electrode 117b of the driving thin film transistor Tdr through an electrode contact hole CH provided in the planarization layer 130 and the protective layer 118.

The light emitting layer EL can be formed on the first electrode E1 and can be directly contact the first electrode E1.

According to one embodiment of the present disclosure, the light emitting layer EL can include two or more organic light emitting layers for emitting white light. For example, the light emitting layer EL can include a first organic light emitting layer and a second organic light emitting layer for emitting white light by mixing first light and second light.

The second electrode E2 is disposed on the light emitting layer EL and can be directly contact the light emitting layer EL. The second electrode E2 can have a relatively thin thickness compared to the light emitting layer EL.

According to one embodiment of the present disclosure, for top emission, the first electrode E1 can have a structure capable of reflecting light, which is emitted from the light emitting layer EL and incident to the first electrode E1, toward the opposite side of the substrate 110. In order to reflect light emitted and incident from the light emitting layer EL toward the opposite side of the substrate 110, the first electrode E1 can include a metal material having high reflectivity. For example, the first electrode E1 can have a single-layer structure or a multi-layer structure made of one material selected from aluminum (Al), silver (Ag), molybdenum (Mo), gold (Au), magnesium (Mg), calcium (Ca), or barium (Ba), or an alloy material of two or more materials but embodiments of the present disclosure are not limited thereto. The first electrode E1 can be an anode electrode.

The second electrode E2 can have light transparency or light transmitting property. one In embodiment of the present disclosure, light transparency can be referred to as light transmitting property. According to one embodiment of the present disclosure, the second electrode E2 can have both light transmitting property and light reflecting property. The second electrode E2 can have a multilayer structure including, for example, a layer made of a transparent conductive oxide (TCO) and a layer made of a metal with a low work function, but embodiments of the present disclosure are not limited thereto. The second electrode E2 can be a cathode electrode.

The display apparatus 100 according to one embodiment of the present disclosure can further include a bank layer 170. The bank layer 170 can be disposed on the edge of the first electrode E1 and the planarization layer 130. The bank layer 170 can be made of a transparent material or an opaque material. For example, the bank layer 170 can be a transparent bank layer or a black bank layer. For example, the bank layer 170 can include a black pigment, in which case the bank layer 170 can also function as a light-blocking member between adjacent sub pixels SP.

The encapsulation layer 180 can be formed on the substrate 110 to surround the organic light emitting element 160. The encapsulation layer 180 can be disposed on the second electrode E2. For example, the encapsulation layer 180 can surround the display area AA. The encapsulation layer 180 can protect the thin film transistor and the light emitting layer EL from external impact and can serve to prevent oxygen, moisture, or foreign particles from penetrating into the light emitting layer EL.

According to one embodiment of the present disclosure, the encapsulation layer 180 can include a plurality of inorganic encapsulating layers. The encapsulation layer 180 can further include at least one organic encapsulating layer interposed between the plurality of inorganic encapsulating layers.

The display apparatus 100 according to one embodiment of the present disclosure can further include a color filter layer 150. The color filter layer 150 can be disposed in a direction in which light is emitted from the organic light emitting element 160. According to one embodiment of the present disclosure, the color filter layer 150 can be disposed on the opposite side of the substrate 110 with the organic light emitting element 160 as the center.

The color filter layer 150 can be disposed on the organic light emitting element 160 so as to overlap with at least one emission area EA. According to one embodiment of the present disclosure, the color filter layer 150 can be disposed on the encapsulation layer 180.

The color filter layer 150 can have a size wider than the emission area EA. For example, an edge portion of the color filter layer 150 can overlap with the bank layer 170. According to one embodiment of the present disclosure, the color filter layer 150 can have a size corresponding to the entire sub pixel area SPA of each sub pixel SP, thereby reducing light leakage between adjacent sub pixels SP.

According to one embodiment of the present disclosure, the color filter layer 150 can be configured to transmit a wavelength of a color set in the sub pixel SP. For example, as illustrated in FIG. 3, when one pixel P includes first, second, third, and fourth sub pixels SP1, SP2, SP3, SP4, the color filter layer 150 can include a red color filter provided in the first sub pixel SP1, a green color filter provided in the third sub pixel SP3, and a blue color filter provided in the fourth sub pixel SP4. The second sub pixel SP2 may not include a color filter layer or can include a transparent material for step compensation, thereby emitting white light.

According to the present disclosure, the color filter layer 150 can be formed on the upper surface of the encapsulation layer 180 so as to overlap with the emission area EA. For example, the color filter layer 150 can contact the upper surface of the encapsulation layer 180. However, one embodiment of the present disclosure is not limited thereto, and a transparent adhesive member can be disposed between the encapsulation layer 180 and the color filter layer 150.

The display apparatus 100 according to one embodiment of the present disclosure can further include a black matrix 155 disposed between color filters of a color filter layer 150.

The black matrix 155 can be disposed to overlap with the remaining area except for the emission area EA of each sub pixel SP. However, one embodiment of the present disclosure is not limited thereto, and the remaining area except for the emission area EA of each sub pixel SP can include a stacked structure of at least two or more color filters instead of the black matrix 155. For example, the remaining area except for the emission area EA of each sub pixel SP can include a stacked structure of at least two or more color filters among a red color filter, a green color filter, and a blue color filter. The stacked structure of at least two or more color filters can prevent color mixing between adjacent sub pixels SP instead of the black matrix 155.

Referring to FIG. 4, an overcoating layer 185 can be disposed on the color filter layer 150. The overcoating layer 185 can protect the color filter layer 150 and flatten the upper portion of the color filter layer 150. The overcoating layer 185 can also be referred to as a protective layer. The overcoating layer 185 can also be omitted.

According to one embodiment of the present disclosure, the laminate from the substrate 110 to the color filter layer 150 is referred to as a display panel 310. Referring to FIG. 4, the laminate from the substrate 110 to the overcoating layer 185 can also be referred to as a display panel 310.

The display apparatus 100 according to one embodiment of the present disclosure includes the optical improvement layer 210 disposed on a display panel 310. A first adhesive member 190 can be disposed between the display panel 310 and the optical improvement layer 210. The optical improvement layer 210 can be attached and fixed to the display panel 310 by the first adhesive member 190.

Referring to FIG. 4, the display apparatus 100 can include a cover substrate 250. An optical improvement layer 210 can be disposed between the display panel 310 and the cover substrate 250. In addition, a second adhesive member 290 can be disposed between the optical improvement layer 210 and the cover substrate 250. The optical improvement layer 210 can be attached and fixed to the cover substrate 250 by the second adhesive member 290.

As the cover substrate 250, a glass substrate or a transparent plastic substrate can be used. The light generated from the organic light emitting element 160 of the display panel 310 can be emitted to the outside through the cover substrate 250. In addition, external light can be incident through the cover substrate 250, and the external light can be reflected by the cover substrate 250.

When external light is reflected from the cover substrate 250, the glare occurs on the cover substrate 250, and an image reflected on the cover substrate 250 can be visible to the user. To prevent such glare phenomenon and the phenomenon of seeing the reflected image, the cover substrate 250 can be subjected to an anti-glare treatment or a matte treatment. The anti-glare treatment or matte treatment for the cover substrate 250 can include, for example, forming a fine pattern on the cover substrate 250 or performing a roughening treatment.

The fine pattern or roughness treatment pattern formed on the cover substrate 250 is a random pattern. However, due to the irregularity or non-uniformity of the multiple randomly arranged patterns, a sparkling phenomenon or a sandy phenomenon can occur.

The sparkling phenomenon refers to a phenomenon in which bright areas and dark areas are irregularly perceived as spots on a display surface, corresponding to the intervals between patterns. This sparkling phenomenon is particularly noticeable in a display apparatus 100 including a self-luminous light emitting element. For example, in a display panel 310 including an organic light emitting element 160, which is a self-luminous display element, when light generated from the organic light emitting element 160 is emitted to the outside through the display panel 310 and the cover substrate 250, bright areas and dark areas can be irregularly perceived as small bubbles on the display surface, corresponding to the intervals between a plurality of randomly arranged patterns. This phenomenon in which shapes like small bubbles are irregularly perceived is called a sparkling phenomenon.

Meanwhile, the display apparatus 100 has a structure in which multiple layers having various functions are laminated. When light is incident from the outside of the display apparatus 100 (external light incident), reflection and refraction occur in each layer constituting the cover substrate 250 and the display panel 310, and due to the fluctuation deviation of the light reflected or refracted under various conditions, a blurry area similar to sand sprinkled on the area near the point where the reflected external light is recognized can be recognized. In this way, the phenomenon in which a blurry area is recognized near the point where the reflected external light is recognized is called the sandy phenomenon.

In order to prevent or suppress the occurrence of a sparkling phenomenon or a sandy phenomenon in a display apparatus 100, according to one embodiment of the present disclosure, an optical improvement layer 210 is disposed on a display panel 310.

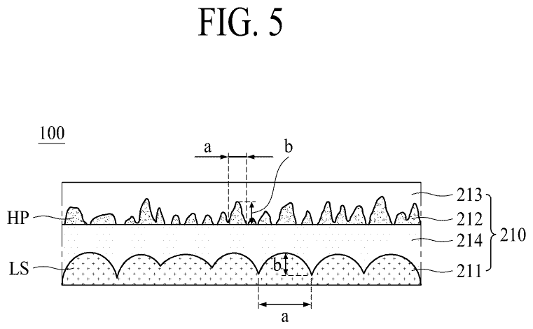

FIG. 5 is a partial cross-sectional view of the optical improvement layer 210 of FIG. 4.

The optical improvement layer 210 includes a first pattern layer 211 and a second pattern layer 212. The first pattern layer 211 and the second pattern layer 212 overlap each other. The first pattern layer 211 has a first refractive index, and the second pattern layer 212 has a second refractive index that is different from the first refractive index.

The first pattern layer 211 and the second pattern layer 212 can each be made of a light-transmitting resin. The light-transmitting resin can also be referred to as a transparent resin.

According to one embodiment of the present disclosure, a light-transmitting resin can be formed by polymerizing a monomer. For polymerization of the monomer, light can be irradiated (photopolymerization) or heat can be applied (thermal polymerization). For example, UV can be used for photopolymerization.

Additionally, to form a light-transmitting resin, curing can be performed after polymerization of the monomer. The curing methods include photocuring and thermal curing. According to one embodiment of the present disclosure, the light-transmitting resin can be formed by UV photocuring using UV light.

The light-transmitting resin can include at least one of polymethyl methacrylate (PMMA) based, polycarbonate (PC) based, polyethylene terephthalate (PET) based, polyurethane (PU) based, and polystyrene (PS) based polymer resins, but embodiments of the present disclosure are not limited thereto.

The first pattern layer 211 and the second pattern layer 212 can be made of materials of the same series or of different series. Even if the first pattern layer 211 and the second pattern layer 212 are made of materials of the same series, the first pattern layer 211 and the second pattern layer 212 can have different refractive indices when the curing conditions are different.

The first pattern layer 211 and the second pattern layer 212 can each independently have a refractive index in the range of, for example, 1.4 to 2.0. Depending on the type of material forming the light-transmitting resin and the curing conditions, the refractive indices of the first pattern layer 211 and the second pattern layer 212 can each be independently adjusted.

Referring to FIG. 4, an intermediate layer 214 can be disposed on the first pattern layer 211. The intermediate layer 214 can have a different refractive index from the first pattern layer 211. The light can be refracted at the interface between the first pattern layer 211 and the intermediate layer 214 due to the refractive index difference between the first pattern layer 211 and the intermediate layer 214.

Referring to FIG. 4, a filling layer 213 can be disposed on the second pattern layer 212. The upper portion of the second pattern layer 212 can be flattened by the filling layer 213. The filling layer 213 can be placed between the patterns HP included in the second pattern layer 212.

The filling layer 213 and the intermediate layer 214 can each be made of a light-transmitting resin. The light-transmitting resin can include at least one of polymethyl methacrylate (PMMA) based, polycarbonate (PC) based, polyethylene terephthalate (PET) based, polyurethane (PU) based, and polystyrene (PS) based polymer resins, but embodiments of the present disclosure are not limited thereto.

The filling layer 213 and the intermediate layer 214 can each independently have a refractive index ranging from, for example, 1.4 to 2.0. Depending on the type of material forming the light-transmitting resin and the curing conditions, the refractive indices of the filling layer 213 and the intermediate layer 214 can each be independently adjusted, but embodiments of the present disclosure are not limited thereto.
According to one embodiment of the present disclosure, as illustrated in FIGS. 4 and 5, the first pattern layer 211 can have a plurality of lens patterns LS. In detail, the first pattern layer 211 can include a plurality of patterns having a lens shape. Hereinafter, the patterns having a lens shape are referred to as lens patterns LS. In embodiments of the present disclosure, the plurality of lens patterns LS can have one or more apexes. One or more of apexes can be rounded or curved. In this regard, when viewed in cross section, the plurality of lens patterns LS can have curved or convex profiles.

Each of the plurality of lens patterns LS included in the first pattern layer 211 can have a different size. The first pattern layer 211 can be formed by arranging a plurality of lens patterns LS having non-uniform sizes on a single plane.

The first pattern layer 211 can have an average pattern size of 20 to 50 μm. The average pattern size can be referred to as the average size of a plurality of lens patterns LS included in the first pattern layer 211.

According to one embodiment of the present disclosure, in a planar image of the first pattern layer 211, the maximum diameter of each of a plurality of patterns is measured, an average of these is calculated, and the average value can be referred to as an average pattern size. Accordingly, the average pattern size can be referred to as an average value of the maximum diameter of each of the plurality of patterns in the planar image of the first pattern layer 211.

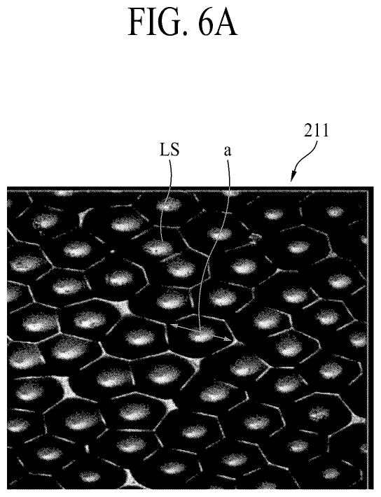

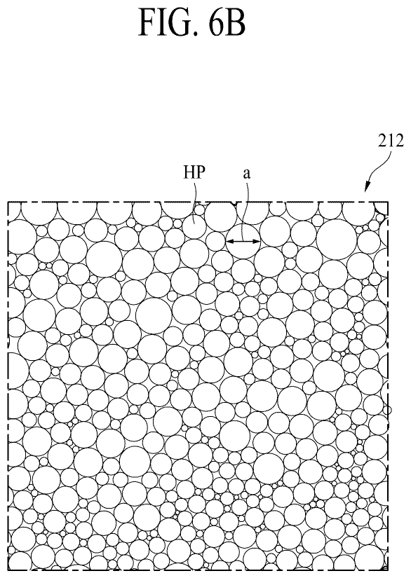

FIG. 6A is a plan view of the first pattern layer 211. In FIG. 6A, each lens pattern LS can be defined by the boundaries of the patterns. In addition, as illustrated in FIG. 6A, the maximum diameter a for each of the plurality of patterns can be said to be the maximum length in each lens pattern LS displayed in a plane.

The average pattern size of the first pattern layer 211 can be the average size of the plurality of lens patterns LS included in the first pattern layer 211. When the first pattern layer 211 has an average pattern size of 20 to 50 μm, the phenomenon of Mura being visible due to external light can be effectively prevented or suppressed.

When external light is incident on the display apparatus 10 and reflected, coherence can occur due to diffraction by elements constituting the display apparatus 100, and a rainbow spot pattern or a circular ring-shaped pattern can occur due to coherence. Such a pattern is called Mura. Mura can also be referred to as reflection diffraction Mura, Rainbow Mura, or the like. According to one embodiment of the present disclosure, Mura can be prevented or suppressed by the first pattern layer 211 including a plurality of lens patterns LS having an average pattern size of 20 to 50 μm.

In detail, the first pattern layer 211 can have an average pattern size of 30 to 40 μm, and can also have an average pattern size of about 35 μm.

According to one embodiment of the present disclosure, the first pattern layer 211 can have an arithmetic mean roughness (Ra) of 1.7 to 3.7 μm. The arithmetic mean roughness (Ra) can be measured using a surface roughness measuring device according to the JIS (Japanese Industrial Standard) B 0601 standard.

In detail, the first pattern layer 211 can have an arithmetic mean roughness (Ra) in the range of 2.0 to 3.5 μm, can have an arithmetic mean roughness (Ra) in the range of 2.5 to 3.0 μm, and can have an arithmetic mean roughness (Ra) of about 2.7 μm.

Additionally, the first pattern layer 211 can have an average width (Rsm) of 130 to 170 μm. The average width (Rsm) can be defined as an average value for the distances of profile elements within a sampling length. The average width (Rsm) can be measured using a surface roughness measuring device according to the JIS B 0601 standard. Since the average width (Rsm) is an average width within a sampling length, it can differ from the size of an individual single pattern.

In detail, the first pattern layer 211 can have an average width (Rsm) of 140 to 160 μm, can have an average width (Rsm) of 145 to 155 μm, or can have an average width (Rsm) in the range of 150 to 153 μm.

According to one embodiment of the present disclosure, a first pattern layer 211 having an average pattern size of 20 to 50 μm, an arithmetic mean roughness (Ra) of 1.7 to 3.7 μm, and an average width (Rsm) of 130 to 170 μm is used in a laminated manner with a second pattern layer 212, thereby preventing or suppressing a sparkling phenomenon and a sandy phenomenon occurring in a display apparatus 100.

According to one embodiment of the present disclosure, a second pattern layer 212 can be disposed on a first pattern layer 211.

The second pattern layer 212 can include a plurality of patterns HP having a horn-shaped shape. The patterns HP included in the second pattern layer 212 can have a sharp protrusion shape. In embodiments of the present disclosure, the plurality of patterns HP can have one or more apexes. One or more of apexes can be sharp or pointy. In this regard, when viewed in cross section, the plurality of patterns HP can have jagged and/or irregular profiles.

Each of the plurality of patterns HP included in the second pattern layer 212 can have a different size. The second pattern layer 212 can be formed by arranging a plurality of horn-shaped patterns HP having non-uniform sizes on a single plane.

According to one embodiment of the present disclosure, the second pattern layer 212 has a smaller average pattern size than the first pattern layer 211.

The second pattern layer 212 can have an average pattern size of, for example, 2 to 5 μm. The average pattern size of the second pattern layer 212 can be defined as an average value of the maximum diameter of each of the plurality of patterns HP in a planar image of the second pattern layer 212, but embodiments of the present disclosure are not limited thereto.

FIG. 6B is a plan view of the second pattern layer 212. In FIG. 6B, each horn-shaped pattern HP can be defined by the boundaries of the patterns. In addition, as illustrated in FIG. 6B, the maximum diameter (a) for each of the plurality of patterns can be said to be the maximum length in each pattern HP displayed in the plane.

In detail, the second pattern layer 212 can have an average pattern size of 3 to 4 μm, and can also have an average pattern size of about 3.5 μm.

According to one embodiment of the present disclosure, the second pattern layer 212 can have an arithmetic mean roughness (Ra) of 0.4 to 0.7 μm. The arithmetic mean roughness (Ra) can be measured using a surface roughness measuring device according to the JIS (Japanese Industrial Standard) B 0601 standard.

In detail, the second pattern layer 212 can have an arithmetic mean roughness (Ra) in the range of 0.5 to 0.6 μm, and can also have an arithmetic mean roughness (Ra) of about 0.53 μm.

According to one embodiment of the present disclosure, the second pattern layer 212 can have an average width (Rsm) of 60 to 100 μm. The average width (Rsm) can be measured using a surface roughness measuring device according to the JIS B 0601 standard.

In detail, the second pattern layer 212 can have an average width (Rsm) of 70 to 90 μm, can have an average width (Rsm) of 75 to 85 μm, or can have an average width (Rsm) of about 80 μm.

Additionally, the average of the pattern ratio (first average pattern ratio) of the patterns included in the first pattern layer 211 is smaller than the average of the pattern ratio (second average pattern ratio) of the patterns included in the second pattern layer 212.

Here, the average pattern size is, as described above, the average value of the maximum diameter of each of the plurality of patterns in the planar images for each of the first pattern layer 211 and the second pattern layer 212. In addition, the pattern ratio is calculated as “b/a” when the maximum diameter of each pattern is “a” and the height is “b”. The average of the pattern ratio is calculated as the average value of the pattern ratio for the plurality of patterns. In various embodiments of the present disclosure, the pattern ratio b/a of the first pattern layer 211 can be less than or equal to 1.0, where b is less than or equal to a, but embodiments of the present disclosure are not limited thereto, and the pattern ratio b/a of the first pattern layer can be greater than 1.0, where b is greater than a. Also, in various embodiments of the present disclosure, the pattern ratio b/a of the second pattern layer 212 can be greater than equal to 1.0, where b is greater than or equal to b, but embodiments of the present disclosure are not limited thereto, and the pattern ratio b/a of the second pattern layer can be less than 1.0, where b is less than a.

According to one embodiment of the present disclosure, when the first pattern layer 211 and the second pattern layer 212 are laminated in an overlapping manner, the first pattern layer 211 has a larger average pattern size than the second pattern layer 212, and the average of the pattern ratio of the patterns included in the first pattern layer 211 is smaller than the average of the pattern ratio of the patterns included in the second pattern layer 212, a sparkling phenomenon and a sandy phenomenon occurring in the display apparatus 100 can be prevented or suppressed.

With reference to FIGS. 5, 6A and 6B, for example, heights of the plurality of patterns HP included in the second pattern layer 212 can generally vary or be irregular to each other, whereby heights of some of the plurality of patterns HP are greater than those of the other of the plurality of patterns HP by about 0.5 times to about 5 times or more when there is a variance. Also, diameters of the plurality of patterns HP included in the second pattern layer 212 can generally vary in dimensions or sizes, whereby diameters of some of the plurality of patterns HP are greater than those of the other of the plurality of patterns HP by about 0.5 times to about 5 times or more when there is a variance, but embodiments of the present disclosure are not limited thereto.

Also, heights of the plurality of lens patterns LS included in the first pattern layer 211 can generally be similar or be regular to each other, whereby heights of some of the plurality of lens patterns LS are the same or similar to those of the other of the plurality of lens patterns LS or vary by about 0.4 times or less when there is a variance. Also, diameters of the plurality of lens patterns LS included in the first pattern layer 211 can be similar or the same, whereby diameters of some of the plurality of lens patterns LS are greater than those of the other of the plurality of lens patterns LS by about 0.4 times or less when there is a variance, but embodiments of the present disclosure are not limited thereto.

With further reference to FIG. 6A, the plurality of lens patterns LS included in the first pattern layer 211 can contact each other and form a polygon shape at their bases in a plan view. In various embodiments of the present disclosure, the bases of the plurality of lens patterns LS can form a hexagonal pattern. Also, with reference to FIG. 6B, the plurality of patterns HP included in the second pattern layer 212 can contact each other and form interstitial patterns in a plan view, where the plurality of patterns HP having comparatively smaller diameters are interstitially located between the plurality of patterns HP having comparatively larger diameters.

Additionally, with references to FIGS. 5, 6A and 6B, each lens pattern LS of the plurality of lens patterns LS has an apex corresponding to the height “b”, while each pattern HP of the plurality of patterns HP have an apex corresponding to the height “b”. When the plurality of the lens patterns LS are arranged to overlap the plurality of patterns HP, each lens pattern LS overlaps a plurality of patterns HP. For example, a plurality of apexes of the plurality of patterns HP correspond to an apex of a lens pattern LS.

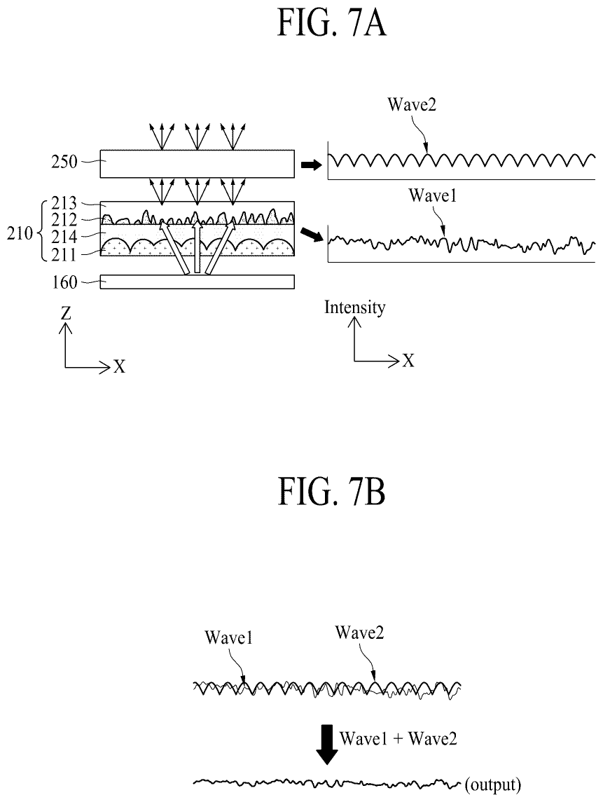

FIG. 7A and FIG. 7B are schematic diagrams explaining a mechanism by which a sparkling phenomenon is eliminated. In the waveform graphs shown on the right side of FIG. 7A and FIG. 7B, the horizontal direction represents the X-direction of the display apparatus 100, and the vertical direction represents the intensity of light.

As shown in FIG. 7A, when the display apparatus 100 is in the ON state, the organic light emitting element 160 included in the display panel 310 is driven, and the organic light emitting element 160 emits light.

In the process of light generated from the organic light emitting element 160 being emitted to the outside, it passes through various layers included in the display panel 310. The light passing through the display panel 310 passes through the optical improvement layer 210. Since the optical improvement layer 210 includes an irregular pattern provided in the first pattern layer 211 and the second pattern layer 212, the light passing through the optical improvement layer 210 can have a waveform such as Wave 1 of FIG. 7A.

Meanwhile, the cover substrate 250 is a flat substrate, and when parallel light passes through the cover substrate 250, it can have a waveform such as Wave 2. Accordingly, when light passing through the optical improvement layer 210 passes through the cover substrate 250, the light after passing through the cover substrate 250 can have a waveform that is a combination of Wave 1 and Wave 2 of FIG. 7A.

As illustrated in FIG. 7B, when Wave 1 and Wave 2 are combined, destructive interference occurs, and light having a waveform as indicated in the lower portion of FIG. 7B is emitted. As illustrated in FIG. 7B, the emitted light, after passing through both the optical improvement layer 210 and the cover substrate 250, has a small deviation in light intensity depending on the position. Therefore, the pattern may not be visible to the user. In this way, when the optical improvement layer 210 according to an embodiment of the present disclosure is used, the sparkling phenomenon can be eliminated or reduced.

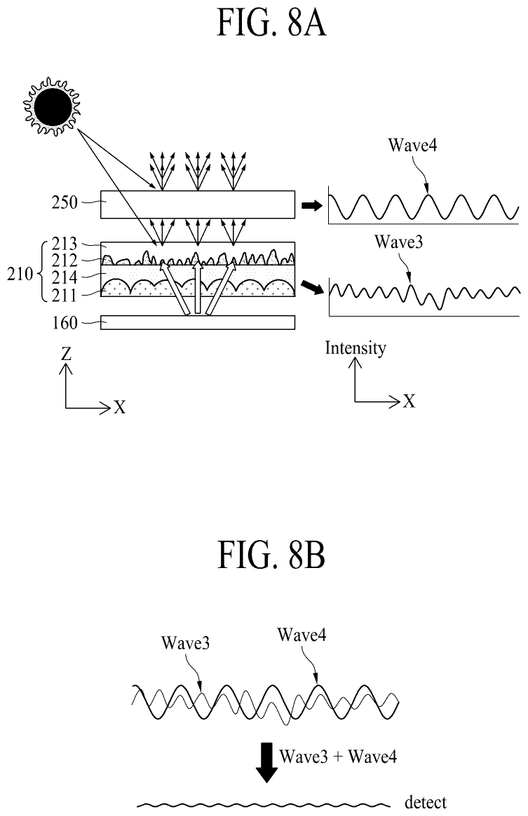

FIG. 8A and FIG. 8B are schematic diagrams explaining the mechanism by which the sandy phenomenon is eliminated.

As shown in FIG. 8A, when the display apparatus 100 is in the OFF state, reflected light due to external light can be noticeably visible to the user.

The light incident on the display apparatus 100 can be reflected by the optical improvement layer 210. Since the light passes through the irregular patterns provided in the first pattern layer 211 and the second pattern layer 212, the light reflected by the optical improvement layer 210 can have a waveform such as Wave 3 of FIG. 8A.

Additionally, external light can be reflected from the cover substrate 250. The light reflected from the cover substrate 250 can have a waveform such as Wave 4 of FIG. 8A.

The user sees both the light reflected from the optical improvement layer 210 and the light reflected from the cover substrate 250. Therefore, the light seen by the user can have a waveform that is a combination of Wave 3 and Wave 4 of FIG. 8A.

As illustrated in FIG. 8B, when Wave 3 and Wave 4 are combined, destructive interference occurs, and light having a waveform as indicated in the lower portion of FIG. 8B is detected by the user. As illustrated in FIG. 8B, the light detected by the user has a small deviation in light intensity depending on the location. Therefore, the pattern may not be visible to the user. In this way, when the optical improvement layer 210 according to an embodiment of the present disclosure is used, the sandy phenomenon can be eliminated or reduced.

The refraction occurs in the optical improvement layer 210 to eliminate or reduce the sparkling phenomenon and the sandy phenomenon. In detail, the refraction of light occurs at the interface between the first pattern layer 211 and the intermediate layer 214 and at the interface between the second pattern layer 212 and the filling layer 213.

According to one embodiment of the present disclosure, as illustrated in FIG. 4 and FIG. 5, the intermediate layer 214 can contact the first pattern layer 211. In addition, the first pattern layer 211 and the intermediate layer 214 can have a refractive index difference of 0.05 to 0.1. Due to this refractive index difference, the light refraction can occur between the first pattern layer 211 and the intermediate layer 214.

When the refractive index difference between the first pattern layer 211 and the intermediate layer 214 is less than 0.05, significant refraction may not occur at the boundary between the first pattern layer 211 and the intermediate layer 214. In addition, when the refractive index difference between the first pattern layer 211 and the intermediate layer 214 exceeds 0.1, light generated from the organic light emitting element 160 can have difficulty being emitted to the outside due to excessive refraction, and light loss due to total reflection can occur. Therefore, according to one embodiment of the present disclosure, the refractive index difference between the first pattern layer 211 and the intermediate layer 214 can be adjusted to a range of 0.05 to 0.1.

According to one embodiment of the present disclosure, as illustrated in FIG. 4 and FIG. 5, the filling layer 213 can contact the second pattern layer 212. In addition, the second pattern layer 212 and the filling layer 213 can have a refractive index difference of 0.05 to 0.1. Due to this refractive index difference, the light refraction can occur between the second pattern layer 212 and the filling layer 213.

When the refractive index difference between the second pattern layer 212 and the filling layer 213 is less than 0.05, significant refraction may not occur at the interface between the second pattern layer 212 and the filling layer 213. In addition, when the refractive index difference between the second pattern layer 212 and the filling layer 213 exceeds 0.1, light generated from the organic light emitting element 160 can have difficulty being emitted to the outside due to excessive refraction, and light loss due to total reflection can occur. Therefore, according to one embodiment of the present disclosure, the refractive index difference between the second pattern layer 212 and the filling layer 213 can be adjusted to a range of 0.05 to 0.1.

According to one embodiment of the present disclosure, the intermediate layer 214 can contact the first pattern layer 211 and the second pattern layer 212.

According to one embodiment of the present disclosure, the light extraction efficiency of the display apparatus 100 can be improved by allowing light to pass straight through the intermediate layer 214 and the second pattern layer 212 without being refracted. To this end, the difference in refractive index between the intermediate layer 214 and the second pattern layer 212 can be adjusted to 0.01 or less. When the difference in refractive index between the intermediate layer 214 and the second pattern layer 212 is 0.01 or less, light passing through the intermediate layer 214 can be incident on the second pattern layer 212 without being refracted.

In detail, the intermediate layer 214 can have the same refractive index as the second pattern layer 212. Additionally, the intermediate layer 214 can be made of the same material as the second pattern layer 212.

The refractive indices of the first pattern layer 211, the second pattern layer 212, the filling layer 213, and the intermediate layer 214 can vary depending on the materials used, curing conditions, or the like., and the refractive indices of each layer can be adjusted independently.

According to one embodiment of the present disclosure, the difference in refractive index between the first pattern layer 211 and the intermediate layer 214 can be equal to the difference in refractive index between the second pattern layer 212 and the filling layer 213. In this case, the number of cases related to refractive index can be reduced, thereby facilitating the design of the display apparatus 100.

The filling layer 213 can have the same refractive index as the cover substrate 250. In addition, the second adhesive member 290 between the filling layer 213 and the cover substrate 250 can also have the same refractive index as the filling layer 213 and the cover substrate 250. In this case, when light generated from the organic light emitting element 160 passes through the filling layer 213, the second adhesive member 290, and the cover substrate 250 and is emitted to the outside, unnecessary light loss due to interface reflection can be prevented or reduced.

Referring to FIG. 4, the display panel 310 includes an overcoat layer 185, and a first pattern layer 211 can be disposed on the overcoat layer 185. The overcoat layer 185 can have the same refractive index as the first pattern layer 211. In addition, the first adhesive member 190 between the overcoat layer 185 and the first pattern layer 211 can also have the same refractive index as the overcoat layer 185 and the first pattern layer 211. In this case, unnecessary light loss due to interface reflection when light generated from the organic light emitting element 160 passes through the color filter layer 150, the overcoat layer 185, the first adhesive member 190, and the first pattern layer 211 can be prevented or suppressed.

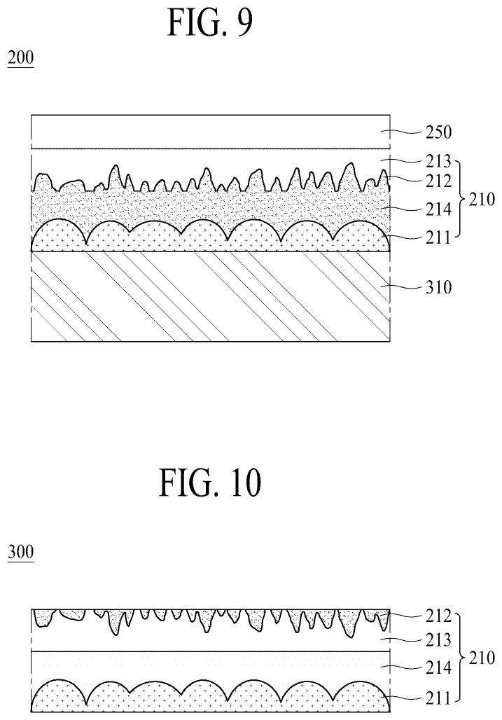

FIG. 9 is a partial cross-sectional view of a display apparatus 200 according to another embodiment of the present disclosure. Hereinafter, descriptions of components already described are omitted to avoid duplication.

Referring to FIG. 9, the intermediate layer 214 and the second pattern layer 212 can be formed integrally. For example, the intermediate layer 214 can be formed on the first pattern layer 211, and the upper surface of the intermediate layer 214 can be patterned so that the upper portion of the intermediate layer 214 becomes the second pattern layer 212, thereby forming the intermediate layer 214 and the second pattern layer 212 integrally.

Since the intermediate layer 214 and the second pattern layer 212 are formed as one body, the light loss between the intermediate layer 214 and the second pattern layer 212 can be minimized or prevented.

Additionally, the first pattern layer 211 and the second pattern layer 212 can have a refractive index difference of 0.05 to 0.1. Since the first pattern layer 211 and the second pattern layer 212 have a refractive index difference, the light refraction can occur at the interface between the first pattern layer 211 and the second pattern layer 212.

Additionally, the second pattern layer 212 and the filling layer 213 can have a refractive index difference of 0.05 to 0.1. Since the second pattern layer 212 and the filling layer 213 have a refractive index difference, light refraction can occur at the interface between the second pattern layer 212 and the filling layer 213.

According to one embodiment of the present disclosure, the first pattern layer 211 and the filling layer 213 can be made of the same material. In addition, the first pattern layer 211 and the filling layer 213 can have the same refractive index. Since the intermediate layer 214 and the second pattern layer 212 in the display apparatus 200 of FIG. 9 are formed integrally, if the first pattern layer 211 and the filling layer 213 have the same refractive index, the difference in refractive index between the first pattern layer 211 and the intermediate layer 214 can be the same as the difference in refractive index between the second pattern layer 212 and the filling layer 213. When the difference in refractive index between the first pattern layer 211 and the intermediate layer 214 is the same as the difference in refractive index between the second pattern layer 212 and the filling layer 213, the number of cases related to refractive index can be reduced, and the selection of materials can be simplified, thereby facilitating the manufacturing and design of the display apparatus 200.

FIG. 10 to FIG. 16 are partial cross-sectional views of an optical improvement layer 210 applied to a display apparatus according to another embodiment of the present disclosure, respectively.

Referring to FIG. 10, in an optical improvement layer 210 of a display apparatus 300 according to another embodiment of the present disclosure, a filling layer 213 and an intermediate layer 214 can be disposed between a first pattern layer 211 and a second pattern layer 212. The filling layer 213 and the intermediate layer 214 can contact each other.

In detail, the intermediate layer 214 can contact the first pattern layer 211 and the filling layer 213, and the filling layer 213 can contact the second pattern layer 212 and the intermediate layer 214.

The optical improvement layer 210 illustrated in FIG. 10 corresponds to a structure in which the protrusions of the first pattern layer 211 and the protrusions of the second pattern layer 212 are disposed to face each other. In this case, the first pattern layer 211 and the second pattern layer 212 can be spaced apart from each other as far as possible.

Referring to FIG. 10, the filling layer 213 and the intermediate layer 214 can have the same refractive index. In this case, unnecessary light refraction at the interface between the filling layer 213 and the intermediate layer 214 can be prevented or suppressed, thereby improving the light extraction efficiency of the display apparatus 300. According to another embodiment of the present disclosure, the filling layer 213 and the intermediate layer 214 can be formed of the same material.

Additionally, the first pattern layer 211 and the second pattern layer 212 can have the same refractive index. In detail, the first pattern layer 211 and the second pattern layer 212 can be made of the same material.

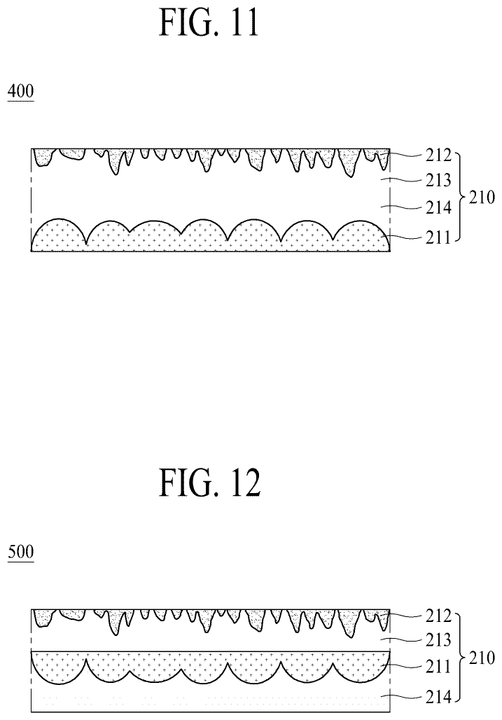

FIG. 11 illustrates an optical improvement layer 210 of a display apparatus 400 according to another embodiment of the present disclosure. Referring to FIG. 11, the filling layer 213 and the intermediate layer 214 can be formed integrally. The structure of FIG. 11 can also be said to be a structure in which the first pattern layer 211 and the second pattern layer 212 are formed of the same material.

According to the structure of FIG. 11, since there is no interface between the filling layer 213 and the intermediate layer 214, unnecessary light refraction is prevented or suppressed, so that the light extraction efficiency of the display apparatus 400 can be improved.

In the optical improvement layer 210 illustrated in FIG. 11, the difference in refractive index between the first pattern layer 211 and the intermediate layer 214 can be the same as the difference in refractive index between the second pattern layer 212 and the filling layer 213.

FIG. 12 illustrates an optical improvement layer 210 of a display apparatus 500 according to another embodiment of the present disclosure. Referring to FIG. 12, a filling layer 213 can be disposed between a first pattern layer 211 and a second pattern layer 212. The optical improvement layer 210 illustrated in FIG. 12 can be said to have a structure in which a first pattern layer 211 is disposed on a second pattern layer 212.

Referring to FIG. 12, a first sheet including a first pattern layer 211 and an intermediate layer 214 is created, a second sheet including a second pattern layer 212 and a filling layer 213 is created, and then the first sheet is attached onto the second sheet, thereby creating an optical improvement layer 210 as illustrated in FIG. 12.

When the optical improvement layer 210 illustrated in FIG. 12 is disposed on the display panel 310, the intermediate layer 214 can contact the display panel 310. At this time, the intermediate layer 214 of the optical improvement layer 210 is directly bonded to the display panel 310 without the first adhesive member 190, thereby reducing the distance between the display panel 310 and the first pattern layer 211 and the second pattern layer 212.

At this time, for adhesion of the optical improvement layer 210, the intermediate layer 214 can be made of an adhesive material.

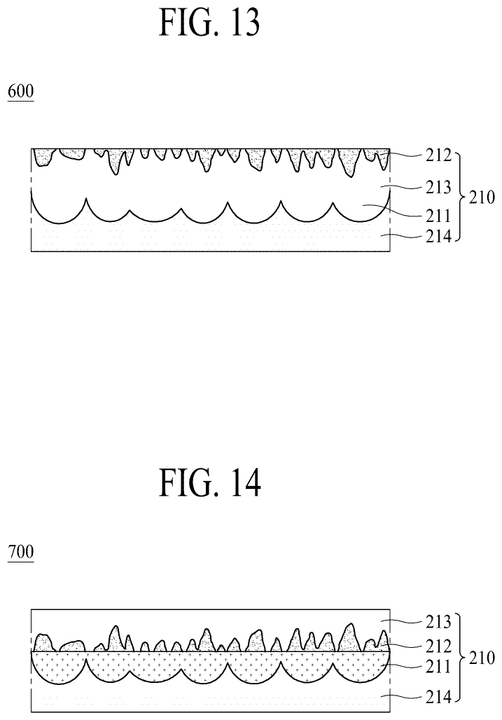

FIG. 13 illustrates an optical improvement layer 210 of a display apparatus 600 according to another embodiment of the present disclosure. The structure illustrated in FIG. 13 corresponds to the structure of the optical improvement layer 210 illustrated in FIG. 12, in which the filling layer 213 and the first pattern layer 211 are formed integrally. Referring to FIG. 13, the filling layer 213 and the first pattern layer 211 can be made of the same material.

In this case, the first pattern layer 211 and the second pattern layer 212 can have a refractive index difference of 0.05 to 0.1. In this case, significant light refraction can occur at the interface between the first pattern layer 211 and the second pattern layer 212.

FIG. 14 illustrates an optical improvement layer 210 of a display apparatus 700 according to another embodiment of the present disclosure. Referring to FIG. 14, a first pattern layer 211 and a second pattern layer 212 can contact each other. At this time, the protrusions of the first pattern layer 211 and the protrusions of the second pattern layer 212 can protrude in opposite directions.

Referring to FIG. 14, a first sheet including a first pattern layer 211 and an intermediate layer 214 is formed, a second sheet including a second pattern layer 212 and a filling layer 213 is formed, and then the first sheet and the second sheet are attached, thereby forming an optical improvement layer 210 as illustrated in FIG. 14. At this time, the first sheet and the second sheet can be attached such that the first pattern layer 211 and the second pattern layer 212 adhere to each other.

When the optical improvement layer 210 illustrated in FIG. 14 is disposed on the display panel 310, the intermediate layer 214 can contact the display panel 310. At this time, the intermediate layer 214 of the optical improvement layer 210 can be directly adhered to the display panel 310 without the first adhesive member 190. For this purpose, the intermediate layer 214 can be made of an adhesive material.

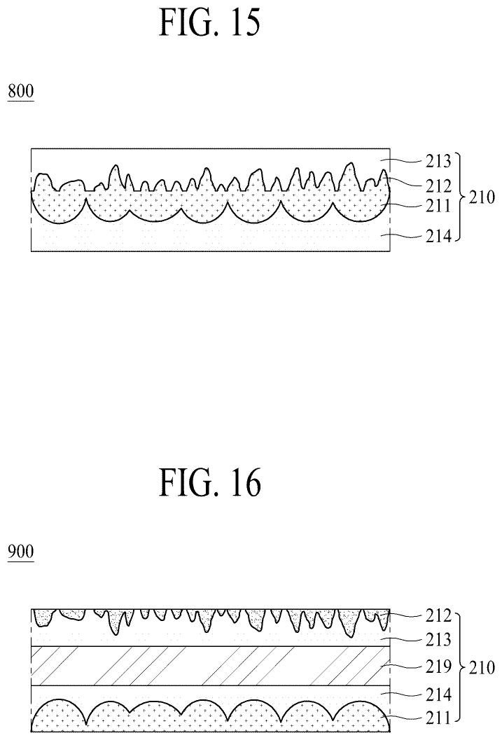

FIG. 15 illustrates an optical improvement layer 210 of a display apparatus 800 according to another embodiment of the present disclosure. The structure illustrated in FIG. 15 corresponds to the structure of the optical improvement layer 210 illustrated in FIG. 14, in which the first pattern layer 211 and the second pattern layer 212 are formed integrally. In this case, the first pattern layer 211 and the second pattern layer 212 can be made of the same material.

FIG. 16 illustrates an optical improvement layer 210 of a display apparatus 900 according to another embodiment of the present disclosure. The optical improvement layer 210 illustrated in FIG. 16 can further include a spacer 219. The spacer 219 can be disposed between the intermediate layer 214 and the filling layer 213.

The optical improvement layer 210 illustrated in FIG. 16 is the same as the structure in which a first pattern layer 211, an intermediate layer 214, a filling layer 213, and a second pattern layer 212 are sequentially arranged as illustrated in FIG. 10, and a spacer 219 is disposed between the intermediate layer 214 and the filling layer 213.

The thickness of the optical improvement layer 210 can be controlled by the spacer 219, and the distance between the first pattern layer 211 and the second pattern layer 212 can be controlled.

With references to FIGS. 9-16, apexes of the plurality of lens patterns LS included in the first pattern layer 211 and the apexes of the plurality of patterns HP included in the second pattern layer 212 can be directed to various directions relative to the display panel 310. For example, the apexes of the plurality of lens patterns LS and the apexes of the plurality of patterns HP can be directed in the same direction as shown in FIGS. 9, 12 and 13. When the apexes of the plurality of lens patterns LS and the apexes of the plurality of patterns HP are directed in the same direction, the apexes can be directed away from the display panel 310 as shown in FIG. 9 or can be directed forward the display panel as shown in FIGS. 12 and 13.

Also, the apexes of the plurality of lens patterns LS and the apexes of the plurality of patterns HP can be directed in different directions from each other as shown in FIGS. 10, 11, 14, 15 and 16. When the apexes of the plurality of lens patterns LS and the apexes of the plurality of patterns HP are directed in different directions from each other, the apexes can face each other as shown in FIGS. 10, 11 and 16 or face away from each other as shown in FIGS. 14 and 15. When the apexes of the plurality of lens patterns LS and the apexes of the plurality of patterns HP are directed in different directions from each other, one of the apexes of the plurality of lens patterns LS and the apexes of the plurality of patterns HP can face towards the display panel 310 while the other face away from the display panel.

Below, with reference to comparative examples, the elimination and reduction of sparkling and sandy phenomena are explained.

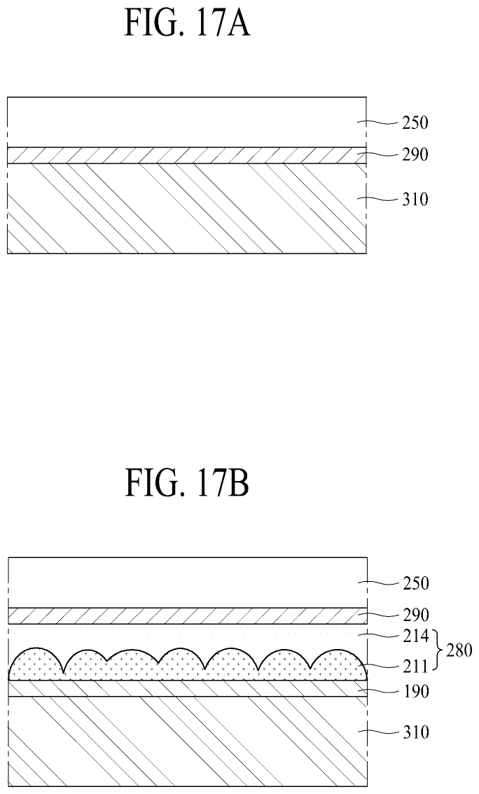

FIG. 17A is a partial cross-sectional view of a display apparatus according to Comparative Example 1, and FIG. 17B is a partial cross-sectional view of a display apparatus according to Comparative Example 2.

The display apparatus (Comparative Example 1) illustrated in FIG. 17A does not include an optical improvement layer 210 according to one embodiment of the present disclosure. The display apparatus (Comparative Example 1) illustrated in FIG. 17A includes a display panel 310, a second adhesive member 290 on the display panel 310, and a cover substrate 250 on the second adhesive member 290.

The display apparatus (Comparative Example 2) illustrated in FIG. 17B does not include the optical improvement layer 210 according to one embodiment of the present disclosure, and includes a lens layer 280. The lens layer 280 includes a first pattern layer 211 and an intermediate layer 214. In detail, the display apparatus (Comparative Example 2) illustrated in FIG. 17B includes a display panel 310, the first adhesive member 190 on the display panel 310, a lens layer 280 on the first adhesive member 190, a second adhesive member 290 on the lens layer 280, and a cover substrate 250 on the second adhesive member 290.

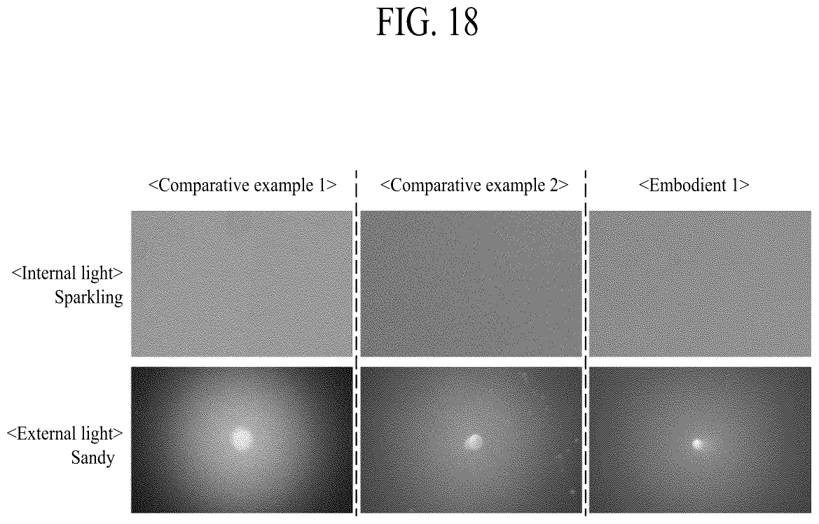

FIG. 18 is an image showing the elimination of sparkling and sandy phenomena.

In FIG. 18, the image shown as “internal light” is a photograph taken of the display surface of the display apparatus when the display apparatus is in the ON state and light is emitted from inside the display apparatus.

In FIG. 18, the image indicated as “external light” is a photograph of the light reflected when a point light source is shined on the display apparatus when the display apparatus 100 is in the off state.

When internal light is emitted from the display apparatuses of Comparative Examples 1 and 2, it can be confirmed that sparkling, such as small bubbles, are generated.

In addition, when the display apparatus is in the OFF state and external light (illumination) is irradiated onto the display apparatuses of Comparative Example 1 and Comparative Example 2, it can be confirmed that a blurry sandy phenomenon occurs as if sand is sprinkled around the point where the external light is reflected.

On the other hand, it can be confirmed that in the display apparatus according to Embodiment 1, sparkling is not generated and a sandy phenomenon does not occur.

Another embodiment of the present disclosure provides an optical improvement layer 210. The optical improvement layer 210 can be formed in a film or sheet shape. The optical improvement layer 210 can be attached to a display panel 310 and used. Since the detailed configuration of the optical improvement layer 210 has already been described in FIG. 5 and FIGS. 9 to 16, a detailed description of the configuration of the optical improvement layer 210 is omitted to avoid duplication.

Hereinafter, with reference to the manufacturing process drawing, a method for manufacturing an optical improvement layer 210 according to one embodiment of the present disclosure will be described.

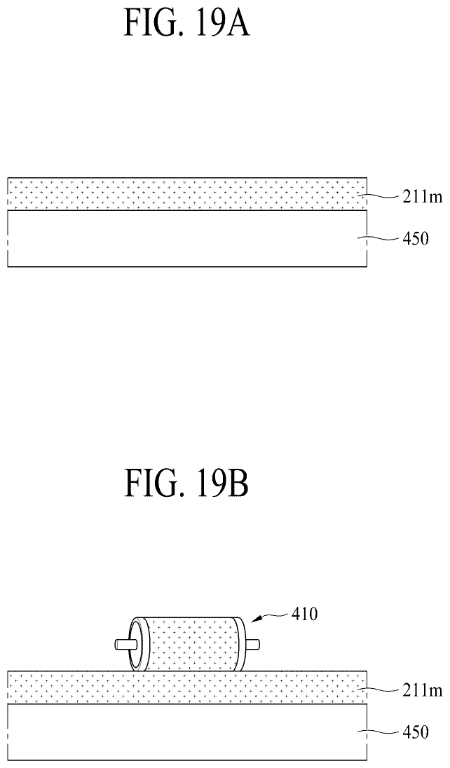

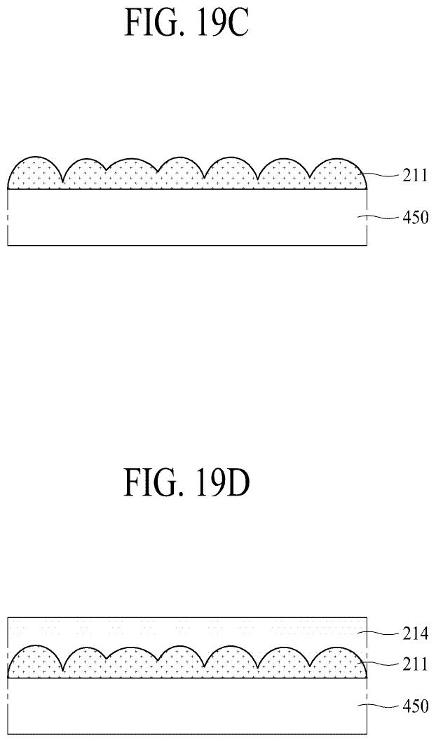

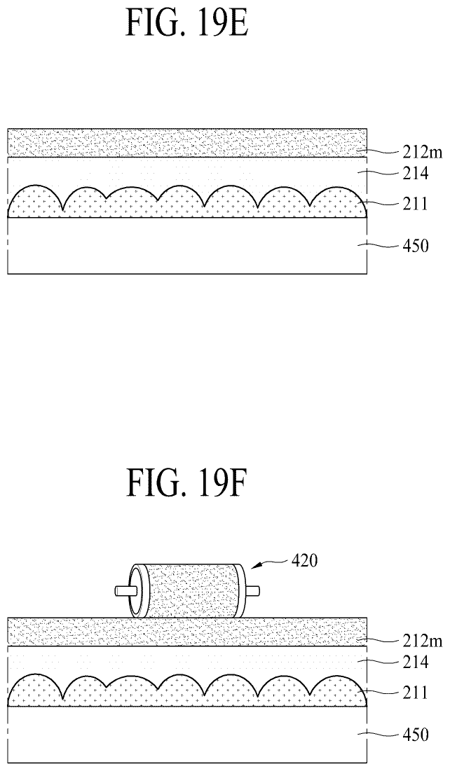

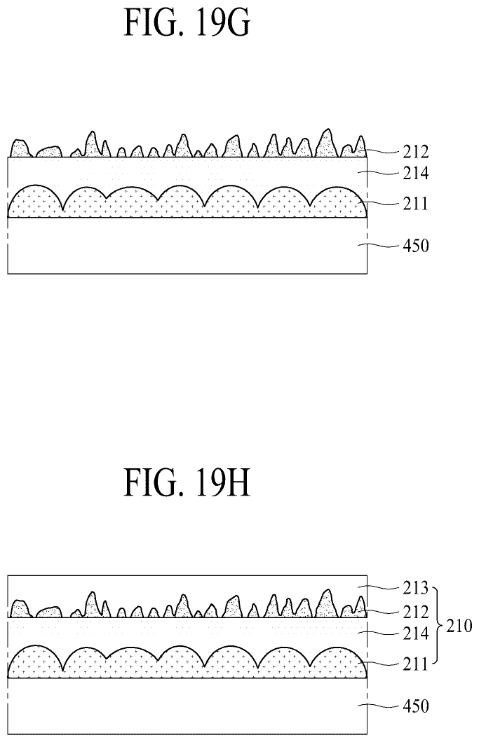

FIG. 19A to FIG. 19H are schematic cross-sectional views illustrating a method for manufacturing an optical improvement layer according to one embodiment of the present disclosure.

Referring to FIG. 19A, a first light-transmitting resin layer 211m is formed on a carrier substrate 450. A glass substrate or a plastic substrate in the form of a film can be used as the carrier substrate 450.

Referring to FIG. 19B, the first light-transmitting resin layer 211m is patterned using the first roller 410. The patterning can be achieved by forming a negative pattern on the first light-transmitting resin layer 211m by the first roller 410.

Referring to FIG. 19C, a first pattern layer 211 is formed by patterning using a first roller 410.

Referring to FIG. 19D, an intermediate layer 214 is formed on the first pattern layer 211. The intermediate layer 214 can be made of a light-transmitting resin.

Referring to FIG. 19E, a second light-transmitting resin layer 212m is formed on the intermediate layer 214.

Referring to FIG. 19F, the second light-transmitting resin layer 212m is patterned using the second roller 420. Patterning can be achieved by forming an engraved pattern on the second light-transmitting resin layer 212m by the second roller 420.

Referring to FIG. 19G, a second pattern layer 212 is formed by patterning using a second roller 420.

Referring to FIG. 19H, a filling layer 213 is formed on the second pattern layer 212. The filling layer 213 can be made of a light-transmitting resin.

As a result, an optical improvement layer 210 as illustrated in FIG. 19H can be created. After the optical improvement layer 210 is created, the carrier substrate 450 is removed.

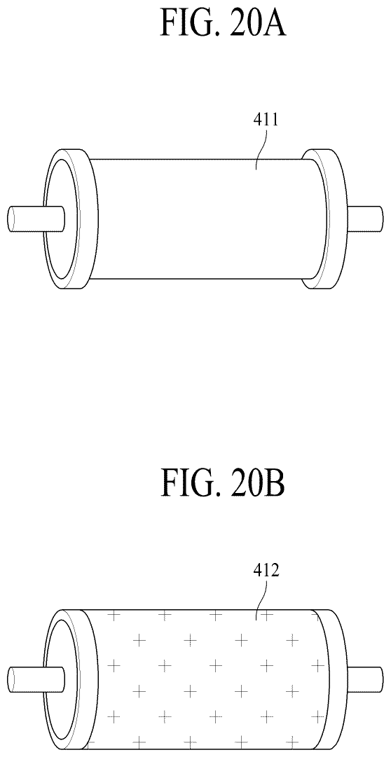

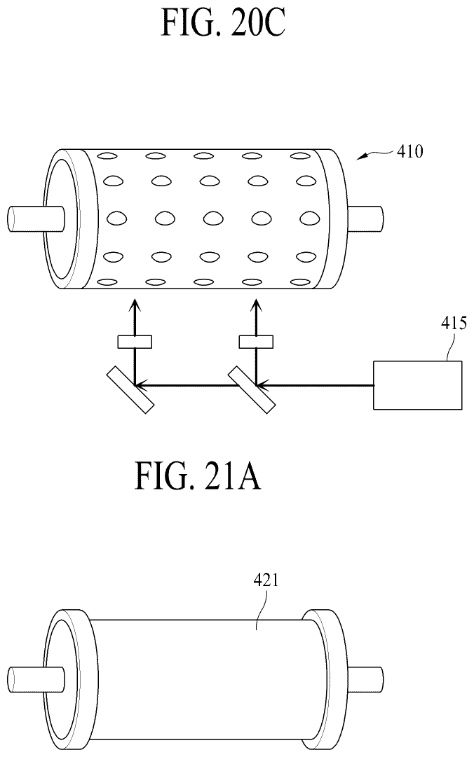

FIG. 20A to FIG. 20C are schematic perspective views illustrating a method for manufacturing a first roller 410 for forming a first pattern layer 211.

Referring to FIG. 20A, a first core 411 is manufactured to manufacture a first roller 410.

Referring to FIG. 20B, a plating layer 412 is formed on the rotating part of the first core 411. The plating layer 421 can include a copper (Cu) plating layer and a nickel (Ni) plating layer.

Referring to FIG. 20C, the plating layer 412 is subjected to laser processing. A laser generating device 415 is used for laser processing.

A hemispherical concave portion corresponding to the lens pattern is formed in the plating layer 412 by laser processing. As a result, a first roller 410 can be produced.

According to one embodiment of the present disclosure, the size of the hemispherical concave portion formed in the plating layer 412 of the first roller 410 is not constant and is random.

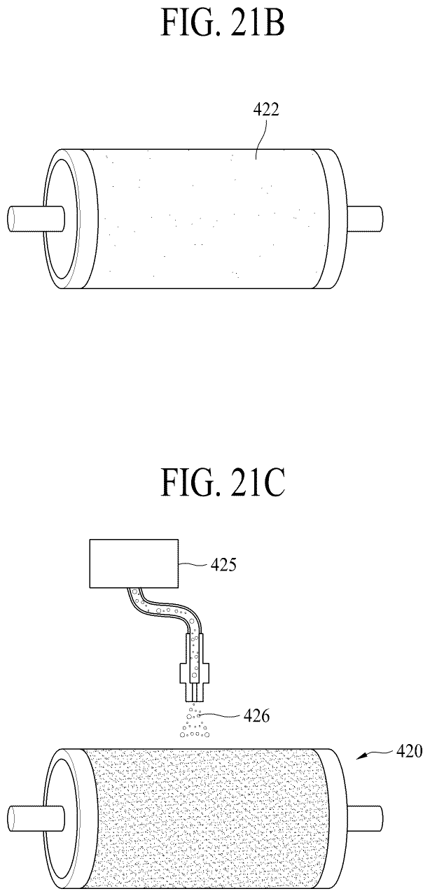

FIG. 21A to FIG. 21C are schematic perspective views illustrating a manufacturing method for a second roller 420 for forming the second pattern layer 212.

Referring to FIG. 21A, the second core 421 is manufactured to manufacture a second roller 420.

Referring to FIG. 21B, the plating layer 422 is formed on the rotating part of the second core 421. The plating layer 422 can include a copper (Cu) plating layer and a nickel (Ni) plating layer.

Referring to FIG. 21C, the plating layer 422 is sand-treated. The sandblasting 425 can be used for the sand treatment. The high-strength fine particles 426, such as emery, are sprayed onto the plating layer 422 by sandblasting 425.

The concave portion corresponding to the horn shape is formed in the plating layer 422 by sand treatment. As a result, a second roller 420 can be produced.

According to one embodiment of the present disclosure, the size of the horn-shaped concave portion formed in the plating layer 422 of the second roller 420 is not constant and is random.

The present disclosure described above is not limited to the above-described embodiments and the attached drawings, and it will be apparent to a person skilled in the art to which the present disclosure pertains that various substitutions, modifications, and changes are possible within a scope that does not depart from the technical details of the present disclosure.

According to one embodiment of the present disclosure, the optical improvement layer including a first pattern layer and a second pattern layer having different pattern shapes and pattern sizes is disposed on a display panel, thereby effectively preventing or suppressing the occurrence of a sparkling phenomenon or a sandy phenomenon in a display apparatus.

The optical sheet according to one embodiment of the present disclosure includes a first pattern layer and a second pattern layer having different pattern shapes and pattern sizes, and can be applied to a display panel to effectively prevent or suppress a sparkling phenomenon or a sandy phenomenon occurring in a display apparatus.

According to the present disclosure, the sparkling phenomenon occurring in a display apparatus when an internal light emitting element emits light (ON state) can be effectively suppressed or prevented, and the sandy phenomenon occurring in a display apparatus when external light is reflected from a display surface can be effectively suppressed or prevented.

According to one embodiment of the present disclosure, the sparkling phenomenon or the sandy phenomenon occurring in the display apparatus can be effectively prevented or suppressed, and the display apparatus can have excellent display quality.

In addition to the effects mentioned above, other features and advantages of the present disclosure are described below or can be clearly understood by those skilled in the art to which the present disclosure pertains from such description and explanation.

What is claimed is:

1. A display apparatus comprising:
a display panel having pixels; and
an optical improvement layer on the display panel;
wherein the optical improvement layer includes a first pattern layer and a second pattern layer overlapping each other,
wherein the first pattern layer has a first refractive index,
wherein the second pattern layer has a second refractive index different from that of the first refractive index,
wherein the first pattern layer has an average pattern size greater than that of the second pattern layer,
wherein an average of pattern ratios of patterns included in the first pattern layer is smaller than an average of pattern ratios of patterns included in the second pattern layer,
wherein the average pattern size is an average value of maximum diameters of respective patterns in a plan-view image for each of the first pattern layer and the second pattern layer,
wherein each pattern ratio is calculated as “b/a,” where “a” denotes a maximum diameter of each pattern, and “b” denotes a height of the each pattern for the patterns included in the first pattern layer and the patterns included in the second pattern layer, and
wherein the average of the pattern ratios is calculated as an average value of the pattern ratios of the respective patterns.

2. The display apparatus of claim 1, wherein the first pattern layer has a plurality of lens patterns, and
wherein the second pattern layer includes a plurality of horn-shaped patterns.

3. The display apparatus of claim 1, wherein the optical improvement layer further includes an intermediate layer on the first pattern layer.

4. The display apparatus of claim 3, wherein the intermediate layer contacts the first pattern layer, and
wherein a refractive index difference between the first pattern layer and the intermediate layer is from about 0.05 to about 0.1.

5. The display apparatus of claim 3, wherein the intermediate layer contacts the first pattern layer and the second pattern layer, and
wherein a refractive index difference between the intermediate layer and the second pattern layer is about 0.01 or less.

6. The display apparatus of claim 3, wherein the intermediate layer includes a same material as that of the second pattern layer.

7. The display apparatus of claim 3, wherein the intermediate layer is formed integrally with the second pattern layer.

8. The display apparatus of claim 7, wherein a refractive index difference between the first pattern layer and the second pattern layer is from about 0.05 to about 0.1.

9. The display apparatus of claim 3, wherein the optical improvement layer further includes a filling layer on the second pattern layer.

10. The display apparatus of claim 9, wherein the filling layer contacts the second pattern layer, and
wherein a refractive index difference between the second pattern layer and the filling layer is from about 0.05 to about 0.1.

11. The display apparatus of claim 9, wherein the intermediate layer and the filling layer are disposed between the first pattern layer and the second pattern layer.

12. The display apparatus of claim 11, wherein the intermediate layer and the filling layer includes a same material.

13. The display apparatus of claim 11, wherein the optical improvement layer further includes a spacer disposed between the intermediate layer and the filling layer.

14. The display apparatus of claim 9, wherein the filling layer is disposed between the first pattern layer and the second pattern layer.

15. The display apparatus of claim 14, wherein the filling layer is formed integrally with the first pattern layer.

16. The display apparatus of claim 9, wherein the first pattern layer contacts the second pattern layer, and
wherein protrusions of the first pattern layer and protrusions of the second pattern layer protrude in opposite directions.

17. The display apparatus of claim 16, wherein the first pattern layer is formed integrally with the second pattern layer.

18. The display apparatus of claim 9, wherein a refractive index difference between the first pattern layer and the intermediate layer is equal to a refractive index difference between the second pattern layer and the filling layer.

19. The display apparatus of claim 9, further comprising:
a cover substrate on the filling layer,
wherein the filling layer has a same refractive index as that of the cover substrate.

20. The display apparatus of claim 1, wherein the display panel includes an overcoat layer,
wherein the first pattern layer is disposed on the overcoat layer, and
wherein the overcoat layer has a same refractive index as that of the first pattern layer.

21. The display apparatus of claim 1, wherein the display panel includes a color filter layer, and
wherein the optical improvement layer is disposed on the color filter layer.

22. An optical improvement layer for a display device, the optical improvement layer comprising:
a first pattern layer and a second pattern layer overlapping each other,
wherein the first pattern layer has a first refractive index,
wherein the second pattern layer has a second refractive index different from that of the first refractive index,
wherein the first pattern layer has an average pattern size greater than that of the second pattern layer,
wherein an average of pattern ratios of patterns included in the first pattern layer is smaller than an average of pattern ratios of patterns included in the second pattern layer,
wherein the average pattern size is an average value of maximum diameters of respective patterns in a plan-view image for each of the first pattern layer and the second pattern layer,
wherein each pattern ratio is calculated as “b/a,” where “a” denotes a maximum diameter of each pattern and “b” denotes a height of the each pattern for the patterns included in the first pattern layer and the patterns included in the second pattern layer, and
wherein the average of the pattern ratios is calculated as an average value of the pattern ratios of the respective patterns.

23. A display apparatus comprising:
a display panel having pixels; and
an optical improvement layer on the display panel;
wherein the optical improvement layer includes a first pattern layer and a second pattern layer, the first pattern layer having a first refractive index and first patterns with a first average pattern ratio, and the second pattern layer having a second refractive index and second patterns with a second average pattern ratio,
wherein the first average pattern ratio is smaller than the second average pattern ratio,
wherein a plurality of the second patterns overlap one pattern of the first patterns, and wherein each average pattern ratio of the respective first and second patterns is an average of “b/a,” where “a” is a maximum diameter and “b” is a height of each pattern of the respective first and second patterns.
